(19) United States
(12) Patent Application Publication
(10) Pub. No.: US 2012/0005557 A1
(43) Pub. Date: Jan. 5, 2012

(54) VIRTUAL COPY AND VIRTUAL WRITE OF DATA IN A STORAGE DEVICE

(76) Inventors: Eitan Mardiks, Raanana (IL); Eran Erez, San Jose, CA (US)

(21) Appl. No.: 12/828,029

(22) Filed: Jun. 30, 2010

(51) Int. Cl. G06F 12/02; G06F 11/10; H03M 13/05

(52) U.S. Cl. 714/763; 711/165; 711/E12.002; 714/E11.034

(57) ABSTRACT

A storage device with a memory and a controller, and a method of copying data on a storage device are provided to perform virtual copy and virtual write of data in a storage device without physically storing data in the storage device. The controller includes, or incorporates with an executable module that handles a command to copy data from a source logical address to a destination logical address, where the source logical memory address data is already associated with a first physical memory address storing the data.

### BACKGROUND

Data is stored in storage devices by or via a host device with which the storage device operates. There are situations where the host device sends a command to the storage device to copy data in the storage device, or to write data into a particular memory location in the storage device without “knowing” that the data is already stored in the storage device. Flash based memory devices, such as secure digital (SD) memory cards and the like, are detrimentally affected by excessive data reading and writing operations.

Hence there is a need to enable a more efficient handling of storage commands between a host device and a storage device.

### SUMMARY

Embodiments of the present invention are defined by the claims, and nothing in this section should be taken as a limitation on those claims. By way of example, the embodiments described in this document and illustrated in the attached drawings generally relate to a storage device with a memory and a controller, and to a method of copying (or writing) data in a storage device, in which the copying (or writing) is performed without physically storing data in the storage device.

In one example, an executable module of the storage device receives a command to copy data from a source logical memory address to a destination logical memory address; and in response associates the destination logical memory address with a physical memory address of where a previous copy of the data is being stored. In another example, the executable module of the storage device receives a command to write data to a destination logical memory address; and in response to identifying a previous copy of the data in a physical memory address on the non-volatile memory, associating the physical memory address with the destination logical memory address.

In sum, a storage device with a memory and a controller, and a method of virtually copying and virtually writing data on a storage device, are provided to handle copy and write requests coming in from a host device without physically storing data in the storage device. The storage device stores data in the memory in physical memory addresses that are associated with logical memory addresses.

These and other embodiments, features, aspects and advantages of the present invention will become better understood from the description herein, appended claims, and accompanying drawings as hereafter described.

### BRIEF DESCRIPTION OF THE DRAWINGS

The accompanying drawings, which are incorporated in and constitute a part of this specification illustrate various aspects of the invention and together with the description, serve to explain its principles. Wherever convenient, the same reference numbers will be used throughout the drawings to refer to the same or like elements.

FIG. 1 is a block diagram of a storage device in which the invention is embodied.

FIG. 2 is a flow diagram of a virtual copy of data in a storage device.

FIG. 3 is a flow diagram of a virtual write of data in a storage device.

FIG. 4 illustrates a logical address to physical address mapping according to an embodiment.

FIG. 5 illustrates a logical address to physical address mapping according to another embodiment.

FIG. 6 shows an example source logical address table.

FIG. 7A shows a data identifier block diagram according to one embodiment.

FIG. 7B shows a data identifier block diagram according to another embodiment.

### DETAILED DESCRIPTION

Various modifications to and equivalents of the embodiments described and shown are possible and various generic principles defined herein may be applied to these and other embodiments. Thus, the claimed invention is to be accorded the widest scope consistent with the principles, features and teachings disclosed herein.

The disclosed embodiments are based, in part, on the observation that a host device may send a command to a storage device to copy data in the storage device, or to write data into a particular memory location in the storage device where the data is already stored in the storage device.

According to one embodiment, in order to take advantage of this feature, when the storage device receives a command to copy data to a destination logical address in the storage device, the storage device may verify whether a previous copy of the data is already stored in the memory and perform a virtual copy process that includes associating the destination logical address with a physical memory location of where a previous copy of the data is being stored. From the standpoint of the host device, the data is stored in two different locations, and is, thus, accessible by using either one of the destination logical address and/or a source logical address associated with the physical address. From the standpoint of the storage device, the data is kept in one physical memory location and read and write operations, which are traditionally performed during conventional data copying (or data writing), may be avoided.

Moreover, when the storage device receives a command to write data to a destination logical address in the storage device, the storage device checks whether a previous copy of the data is already stored therein and, if so, performs a virtual write process in a similar way to a virtual copy process, as mentioned above. In such way, the storage device operates to write the data into the memory only after determining that identical data has not been previously stored in the storage device.

A command to copy data in a storage device may be initiated in various ways. For example, it may be initiated by end-users, by an operating system of a host device, or by an application running on the host device. When initiated by the host device, the copy process depends on the copy methodology used. One copy methodology involves the following steps: (1) the host device sends a read command to the storage device to read the data to be copied; (2) a controller inside the storage device reads the data from a memory location that stores the data; (3) the storage device sends the read data to the host device; and (4) the host device writes the data back into the storage device.

Another copy methodology involves the following steps: (1) the host device sends a copy command to the storage device, where the copy command includes a source address of a memory location in the storage device that stores the data to be copied, and a destination address of a memory location into which the data should be written; (2) the storage device reads the data from the memory by using the source address, and, then, rewrites the data in the memory by using the destination address.

In both cases, the storage device is required to read data from a source location in the memory and, then, to actually rewrite the data into a destination location in the memory. Copying data in a storage device in the ways described above consumes time and computational resources. As the data retention property of flash based memory devices deteriorates as a result of repeated read and write operations, copying data in the ways described above unnecessarily wears the memory device, and, consequently, deteriorates the performance of the storage device as a whole.

The following discussion, therefore, presents exemplary embodiments that include a storage device that features virtual copying and virtual writing of data. In this context, the virtual copying and virtual writing of data generally includes updating address mapping tables, but refraining from actually reading data from one memory location in the storage device and physically writing the data in another memory location in the storage device.

Specifically, the exemplary embodiments are provided to address the problem resulting from unnecessary read and write operations in a storage device when a host device copies data in the storage device, or when the host device writes data into the storage device. In this context, a host device (e.g. host device 150) sending a command to the storage device means that the host device sends a copy command or a write command. Other commands that are issued by the host device to the storage device may be handled by the storage device in a conventional way and, therefore, are not discussed herein.

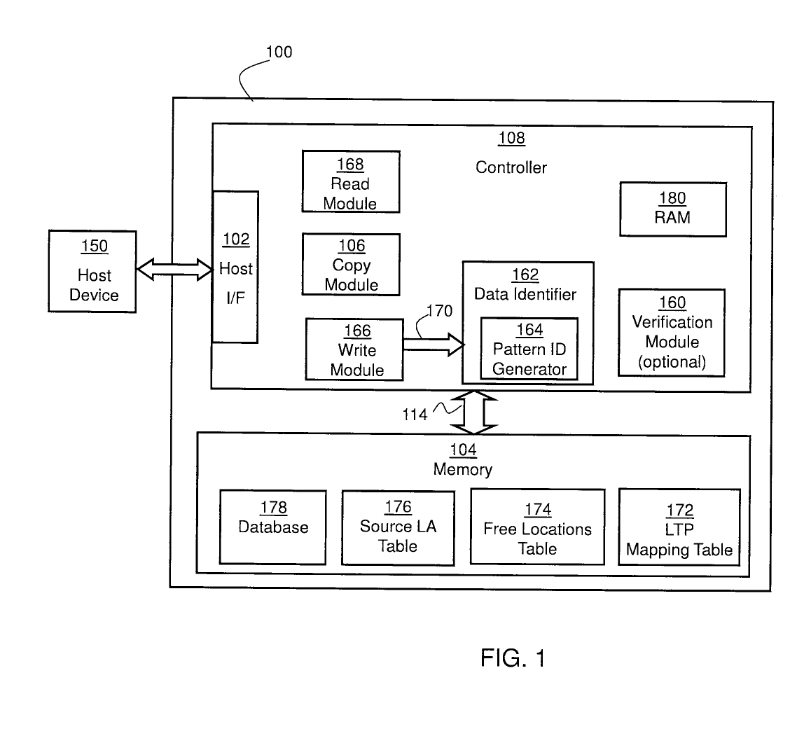

FIG. 1 is a block diagram of a storage device 100 according to one embodiment. Storage device 100 includes a non-volatile memory (“memory”) 104, a controller 108, and a host interface 102 for interfacing with host device 150. Host interface 102 may facilitate wired or wireless communication between controller 108 and host device 150. Storage device 100 stores data in memory 104 in physical memory addresses that are associated with logical memory addresses. Controller 108 includes, or incorporates with a copy module 106, a read module 168, and a write module 166, a verification module 160 (optional), a data identifier 162, a pattern ID generator 164, a random access memory (“RAM”) 180, and a memory interface 114 that interfaces with memory 104. Controller 108 writes data into memory 104 by using write module 166 and reads data from memory 104 by using read module 168. Controller 108 also manages data transfer to and from host device 150 via host interface 102. Data identifier 162 and pattern ID generator 164 can be part of write module 166, or a separate module that are executable on controller 108 and that interoperate with write module 166.

A first module, such as copy module 106, is an executable module on controller 108 operative to receive a command to copy data from a source logical memory address to a destination logical memory address, where the source logical memory address data is already associated with a particular (“first”) physical memory address storing the data; and to perform a virtual copy operation, by associating the first physical memory address with the destination logical memory address as will be described in more detail below. Copy module 106 performs the virtual copy operation such that the data stored in the first physical memory address will be accessible by using either one of the source logical memory address and the destination logical memory address. A second module, such as data identifier 162, being another executable module on controller 108 is operable to identify a previous copy of the data in the storage device.

Memory 104 includes a source logical address (“LA”) table 176, a logical address-to-physical address (“LTP”) mapping table 172, a “free locations table” 174 containing a list of free physical addresses, and a database 178. Source LA table 176, free locations table 174, database 178 and/or LTP table 172 are kept in memory 104, as shown in FIG. 1, and upon power up of storage device may be copied to random access memory (“RAM”) 180 for the purpose of optimizing performance.

LTP mapping table 172 holds memory addresses of physical memory locations (i.e., storage cells) in memory 104. A “physical memory location” is a group or block of contiguous storage cells in memory 104 that is addressable by using a unique physical memory address. By “physical memory address”, or “physical address” for short, is meant a memory address of a physical memory location. LTP mapping table 172 also holds logical memory addresses (“logical addresses” for short) that reference the physical addresses. That is, LTP mapping table 172 includes entries where each entry includes an association between a physical address and a logical address. For example, a logical address “LA1” (not shown in FIG. 1) may reference a physical address “PA1”; a logical address “LA2” may reference a physical address “PA2”, and so on. Traditionally, a physical address is referenced by one logical address.

However, as disclosed herein, a physical address may be referenced by more than one logical address. Physical addresses are usually used internally (by controller 108) to perform storage operations directly on physical memory locations, and logical addresses are usually used by external devices (e.g., host device 150) as a higher level of reference to the physical memory locations. That is, host device 150 stores data in, and obtains data from, storage device 100 by using logical addresses, and storage device 100 performs the required storage operation (e.g., storing or reading the data) by using the corresponding physical addresses. Therefore, from the host device's standpoint the host device stores data in and reads data from logical addresses.

Source LA table 176 includes an entry for each data, or data chunk, that is stored, or that is to be stored, in memory 104. Each entry of source LA table 176 includes a data pattern identifier that represents or characterizes a pattern of bits and the logical address of the pertinent data. The information held in source LA table 176 allows controller 108 to identify and further determine whether data received from host device 150 is already stored in storage device 100 (e.g., in memory 104). If the received data is already stored in storage device 100, controller 108 does not copy the data in memory 104, but rather updates (e.g. adds, modifies, etc.) the appropriate entries in LTP mapping table 172 and source LA table 176, as applicable. If, however, the received data is not yet stored in storage device 100, controller 108 writes the data, for example in memory 104, and updates LTP mapping table 172 and source LA table 176 accordingly. The way LTP mapping table 172 and source LA table 176 are used by controller 108 is described below in more detail. A list of pre-defined and generated data pattern identifiers, or hash values, is typically kept in database 178 in association with the corresponding data of which the data pattern identifiers characterize.

### Copying Data into Memory 104

When host device 150 sends a command (i.e. write or read command) to storage device 100, controller 108 checks whether the command is a “copy” command or a “write” command. If the command is a copy command, the command is handled by copy module 106. As explained above, a copy command includes or specifies a source logical address of the data to be copied, and a destination logical address to which the data is to be copied (also defined herein as “copy particulars”). A copy command may be initiated externally, such as by host device 150, or internally (by controller 108), as explained below.

When host device 150 sends a copy command to storage device 100 to copy data in memory 104, controller 108 does not perform a conventional copy process. Instead, controller 108 invokes copy module 106 to perform a virtual copy operation that includes associating a (source) physical address, where the data is actually stored, with the destination logical address. By performing a virtual copy operation as described herein, data stored in a physical memory address is accessible by using either one of the source logical address and the destination logical address.

If the command is a write command, the command is handled by write module 166, as will further be described below.

In response to copy module 106 receiving copy particulars (i.e., source logical address and destination logical address), copy module 106 may search in LTP mapping table 172 for a logical address that matches the (specified) source logical address of the data to be copied. By using LTP mapping table 172, copy module 106 can retrieve or obtain the physical address that corresponds to the logical address where the data is physically stored. Copy module 106 stores the retrieved physical address in the entry of the destination logical address in LTP mapping table 172, thereby associating between the destination logical address and this physical address. If the destination logical address to which the data is to be copied is not yet contained in LTP mapping table 172, copy module 106 may add a new entry to LTP mapping table 172 and update the new entry with the aforesaid association.

If host device 150 sends another copy command to storage device 100 to copy the (same) data from the source logical address or from the destination logical address to another (i.e., new) destination logical address, copy module 106 likewise associates the other (i.e., new, or second) destination logical address with the physical address that stores the data. In this case, the same physical address would be accessible by using the source logical address, the first destination logical address or the second destination logical address. When the same data is virtually copied multiple times, the logical address to physical address association process described above is repeated as many times as required.

By performing the virtual copy methodology disclosed herein, controller 108 avoids read and write operations that would otherwise be required, frees up the communication bus between host device 150 and storage device 100 for performing other operations and, consequently, may decrease the wear on the storage device 100 (when memory 104 is a flash based storage).

### Interpreting a Write Command as a Virtual Write Command

A copy command can be also generated internally in storage device 100, by controller 108, in response to a write command that is received at controller 108 from host device 150.

In general, host device 150 may issue a command to write data (a write command) into storage device 100. In response to receiving a write command, controller 108 invokes write module 166 to interpret the command before performing a write operation. Write module 166 communicates with data identifier 162 via data and command line(s) 170 to determine whether the specified data is already stored in memory 104 and thus whether to interpret the write command as a virtual write command. Write module 166 then notifies controller 108 accordingly. In other words, write module 166 determines whether the specified data is already stored in memory 104 before actually writing the data, if at all. If the data is already stored in memory 104, controller 108 invokes copy module 106 to perform a virtual copy process, as described above. Thus, a virtual write operation includes identifying a previous copy of the data to be written in memory 104 and then performing a virtual copy process if the data is already in the memory. If the data is not stored in memory 104, write module 166 performs a standard write operation where the data is written to physical addresses in the memory and updates the various address mapping tables, as will further be described below.

Traditionally, write module 166 performs a write operation without operating on data per se, namely; write module 166 changes values of binary bits in memory 104 without identifying the binary bits and without determining which data bits belong to which pattern of data. This means that write module 166 has no means to determine if particular data is already stored in memory 104. Lacking this type of information, when data is received from controller 108, write module 166 would have had to search for the entire data in memory 104. Searching for the entire data in memory 104 would have extensively consumed computation resources, and taken a long time. Therefore, instead of searching every time for an entire data in memory 104, write module 166, by interoperating with data identifier 162, characterizes the data that it receives from host device 150, and uses the characteristics as a searching tool to identify an existing data pattern: if the characteristics of data to be written are identical to stored characteristics, this means that the data to be written is already stored in storage device 100.

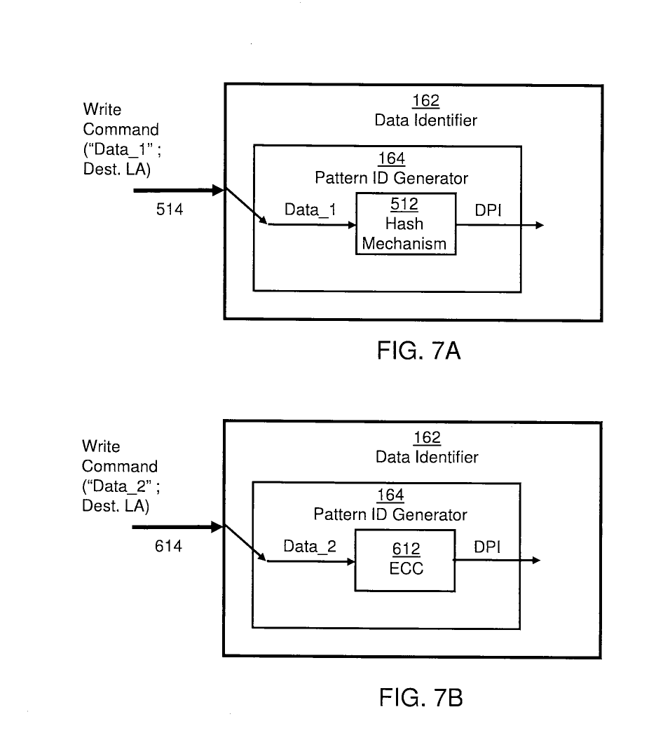

Data identifier 162 characterizes the data that it receives from controller 108 by operating a pattern ID generator 164 that is associated with or, alternatively, embedded within data identifier 162. In general, a pattern ID generator 164 may function or operate as a hashing mechanism that receives a specified data (e.g. data pattern) as its input and generates a corresponding hash value, i.e. a data pattern identifier. A hash value, or a data pattern identifier, typically characterizes the bit-wise pattern of a specified data or pattern of data. By “data” or “pattern of data” is meant an amount of data that is storable in one physical memory location. The size of incoming data received from host device 150 may be as small as the minimal amount of data storable in one physical memory location. If the size of incoming data is larger than this size, pattern ID generator 164 may partition the data to N (N≧2) patterns of data, and generate a corresponding data pattern identifier for each data pattern. Operation of data identifier 162 and pattern ID generator 164 will be explained in further detail below, with respect to FIG. 7A and FIG. 7B.

In response to receiving the write command (or only the data to be written), pattern ID generator 164 generates a data pattern identifier (“DPI”) from the data to be written, or from data patterns that constitute the data.

Then, data identifier 162 accesses database 178 and searches for a data pattern identifier that matches the generated data pattern identifier. If data identifier 162 finds a matching data pattern identifier in database 178 it issues write module 166 a signal, notifying write module 166 that data identical to the data to be written is already stored in memory 104. If data to be written into memory 104 is already stored in memory 104, there is no point in actually rewriting the data. In such case, write module 166 interprets the command as a virtual write command and notifies controller 108 accordingly. Controller 108 uses the matching data pattern identifier to obtain a source logical address of identical data (or of expected to be identical data) previously stored in memory 104. Controller 108, then, transfers the source logical address and the destination logical address to copy module 106, invoking copy module 106 to perform a virtual copy process as described above.

If data identifier 162 does not find a matching data pattern identifier in source LA table 176, this means that the data to be written into memory 104 is not yet stored in memory 104. In such case, write module 166 interprets the write command as a regular write command and, consequently, writes the data in memory 104 and updates source LA table 176 and database 178 for future reference. More specifically, controller 108 transfers to write module 166 the destination logical address as received from host device 150, and write module 166 writes the data in this logical address in memory 104. Write module 166 updates source LA table 176 by creating a new entry in source LA table 176 for the logical address that is received from host device 150 and further updates database 178 by associating between the generated data pattern identifier and the logical address in the new entry. (Note: once the data is written into memory 104 the destination logical address that is received from host device 150 is listed in source LA table 176 as a source logical address)

Whenever data identifier 162 searches for a matching data pattern identifier in source LA table 176, data identifier 162 may access the entries listed in source LA table 176, one or more entries at a time, by using read module 168, for example. Likewise, whenever data identifier 162 creates a new entry in source LA table 176, it updates the new table's entry with the relevant information by using write module 168, for example.

It may occur that even though a data pattern identifier that matches the generated data pattern identifier is found in source LA table 176, the actual data represented by this (matching) data pattern identifier may not be identical to the data to be copied or written. In other words, there is a possibility for a single data pattern identifier to be associated with more than one pattern of data. This may be due to the fact that a data pattern identifier is not uniquely generated for a pattern of data. For this reason there may be a need for controller 108 to apply a verification process for verifying whether the data stored in memory 104 and the data to be copied or written into memory 104 are indeed identical.

Such verification may be achieved by controller 108 interoperating with a verification module 160 (optional unit), invoking verification module 160 to compare between the two sets of data. In this scenario, controller 108 invokes verification module 160 to compare between data that is received from the host (“host-provided” data) and data (“stored data”) actually stored in memory 104. Controller 108 typically provides the stored data to verification module 160 by using LTP mapping table 172. Specifically, controller 108 retrieves the physical address that is associated with the logical address of the host-provided data from LTP mapping table 172, and then obtain the data that is stored in storage device 100 in this physical address. Verification module 160 may perform the verification process by comparing, word by word or every two words for example, between the two sets of data. In case the two data sets are not identical, verification module 160 may perform a regular write operation, or any other predetermined operation.

Note that in some cases, e.g. where a data pattern identifier (DPI) is pre-defined to characterize a particular data pattern, controller 108 need not access LTP mapping table 172 at all. An example for this may include data pattern identifiers that are pre-defined to characterize repetitive data patterns, such as data filled with zeros. In such case, controller 108 may invoke verification module 160 to compare, word by word for example, between the received data and bytes of zeros.

Using a verification module such as verification module 160, therefore, improves the reliability of the virtual copy/write process. Nevertheless, it may be that a search for a data pattern identifier that matches a generated data pattern identifier, as discussed above, may provide sufficient indicia, which meets the particular product needs, for determining whether or not the received data is already stored in storage device 100.

Controller 108 may (e.g. dynamically) update and modify the data pattern identifiers, or hash values stored in database 178 in order to meet up with system performance, usage scenarios, etc. For example, controller 108 may invoke pattern ID generator 164 to modify, or change a data pattern identifier in database 178 in response to and based new incoming data that is received to storage device 100 from host device 150.

Data identifier 162, pattern ID generator 164, copy module 106, (optional) verification module 160, write module 166, and read module 168 that are executed by controller 108 may be implemented in hardware, software, firmware, or in any combination thereof, embedded in or accessible by controller 108.

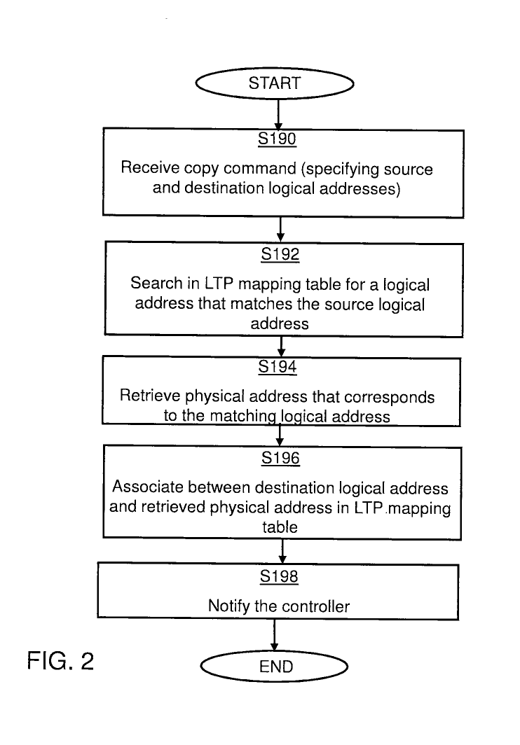

FIG. 2 shows a method for virtual copying of data in a storage device according to an example. FIG. 2 will be described in association with FIG. 1. At step S190, a copy module (such as copy module 106) receives a copy command from controller 108 to copy data in storage device 100. The copy command specifies a source logical address of the data to be copied, and a destination logical address of the copy of the data. As explained above, the copy command that is sent to copy module 106 from controller 108 can be originated from either a copy command or a write command that is transmitted from host device 150.

In response to receiving the copy command, copy module 106 performs a virtual copy operation as follows: At step S192, copy module 106 searches in LTP mapping table 172 for a logical address that matches the (specified) source logical address of the data to be copied. At step S194, copy module 106 retrieves from LTP mapping table 172 the physical address that corresponds to the logical address. Then, at step S196, copy module 106 associates between the destination logical address and the retrieved physical address. Copy module 106 may associate between the two address by storing the retrieved physical address in the entry of the destination logical address in LTP mapping table 172, and if the destination logical address to which the data is to be copied is not yet contained in LTP mapping table 172 copy module 106 adds a new entry to LTP mapping table 172 and updates the new entry with the aforesaid association. At step S198 copy module 106 notifies controller 108, for example by negating a BUSY signal or setting a READY signal, according to the type of the host interface.

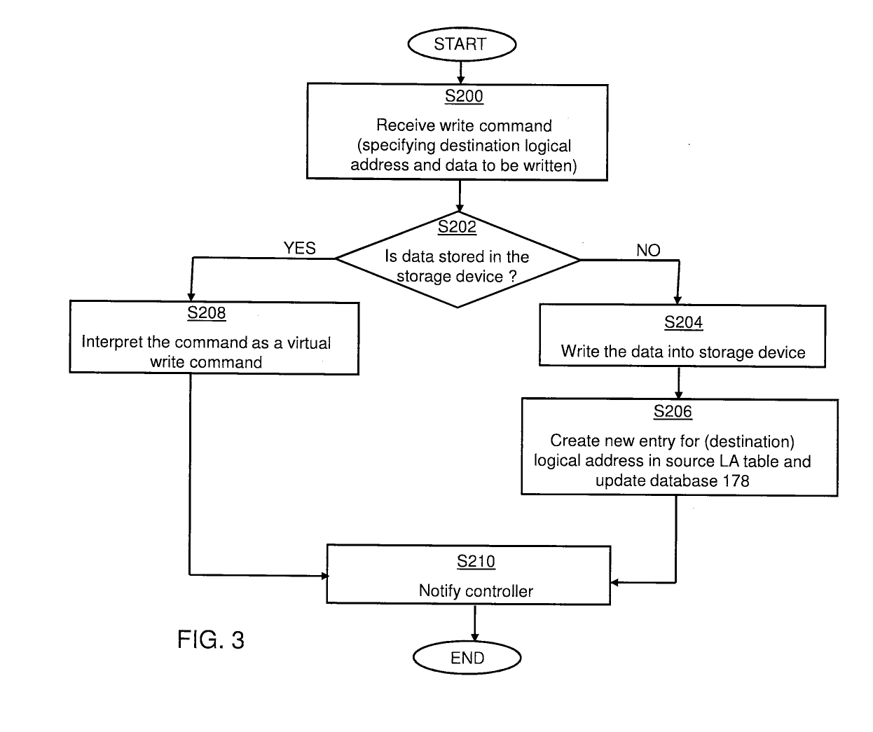

FIG. 3 shows a method for virtual writing of data in a storage device according to an example. FIG. 3 will be described in association with FIG. 1. At step S200, write module 166 receives a write command from controller 108 to write data in storage device 100. The write command, which is originated from host device 150, specifies the data to be written, and a destination logical address of the copy of the data.

In response to receiving the write command, write module 166 checks, at step S202, whether the data to be written is already stored in storage device 100 (e.g., in memory 104). Write module 166 checks whether the data to be written is already stored in storage device 100 by interoperating with a data identifier (such as data identifier 162), which characterizes the data received from the host. Write module 166 uses these characteristics as a searching tool to identify an existing data pattern: if the characteristics of data to be written are identical to characteristics stored in database 178, this means that the data to be written is already stored in storage device 100.

If write module 166 determines that the data to be written is not stored in storage device 100 (shown as “NO” at step S202), write module 166 writes the data in storage device 100 (e.g. memory 104) at step S204, as will be further discussed below, and at step S206 creates a new entry for the (destination) logical address in source LA table 176 and updates database 178 for future reference. Again, once the data is written into memory 104 the destination logical address that is specified by the write command is listed in source LA table 176 as a source logical address. Then, at step S210 write module 166 notifies controller 108 of the completion of the write command accordingly, for example by negating its BUSY signal or setting its READY bit.

However, if write module 166 determines that the data to be written is already stored in storage device 100 (shown as “YES” at step S202), write module 166 interprets, at step S208, the write command as a virtual write command and notifies controller 108 accordingly at step S210. (Interpreting the write command as a virtual write command prompts controller 108 to invoke copy module 160 perform a virtual copy process)

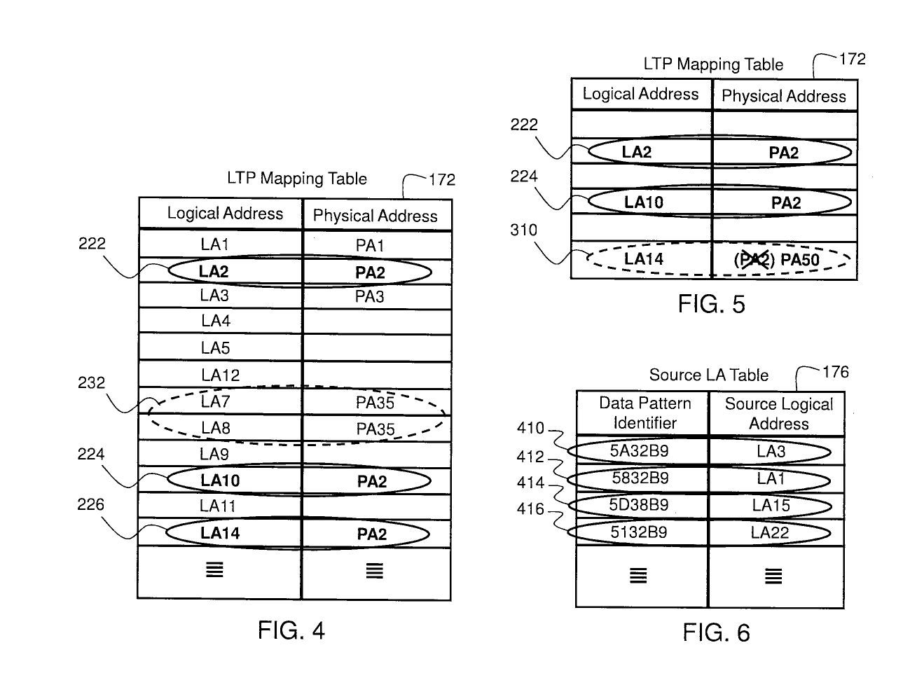

FIG. 4 is an example LTP mapping table 172. FIG. 4 will be described in association with FIG. 1. LTP mapping table 172 includes information regarding associations between logical addresses and physical addresses. LTP mapping table 172 includes an entry for each pattern of data and the information held in each entry associates between a logical address and a physical address of the pertinent pattern of data. By way of example, logical address “LA1” is associated with physical address “PA1”; logical address “LA2” is associated with physical address “PA2”, and so on.

The entries referenced by reference numerals 222, 224, and 226 demonstrate a virtual copy operation. Assume that host device 150 sends a copy command to storage device 100 to copy data that is stored, for example, in logical address “LA2” (Note: logical address “LA2” is shown at 222 associated with example physical address “PA2”). Upon receiving the copy command, controller 108, in conjunction with copy module 106, associates a host-specified destination logical address (e.g., “LA10”) with the same physical address “PA2”. The resulting association between physical address “PA2” and destination logical address “LA10” is shown at 224. This way, the data stored in the physical memory address “PA2” is accessible by using either one of the source logical memory address “LA2” (as per association 222) and the destination logical memory address “LA10” (as per association 224). Therefore, from the host device's standpoint, the copy command was complied with because the data originally stored in logical address “LA2” is also stored now in logical address “LA10”. However, from the memory's standpoint, the data is stored only in one physical place; namely, in physical address “PA2”.

Host device 150 may issue a command to storage device 100 to copy data that is stored in a source logical address (for example logical address “LA2”) to another destination logical address (for example to logical address “LA14”). In response to receiving such a command, controller 108 invokes copy module 106 to handle the command by associating the host-specified destination logical address “LA14” with the same physical address “PA2”. The resulting association between physical address “PA2” and destination logical address “LA14” is shown at 226. This way, the data stored in the physical memory address “PA2” is accessible by using either one of the source logical memory address “LA2” (as per association 222), the logical memory address “LA10” (as per association 224), and the destination logical memory address “LA14” (as per association 226).

Reference numeral 232 demonstrates a virtual write operation. Assume that host device 150 issues a command to storage device 100 to write data into logical address “LA8”, an example destination logical address. Also assume that the data to be written is already stored in logical address “LA7” (Note: logical address “LA7” is shown at 232 associated with example physical address “PA35”). Upon receiving the write command, controller 108 invokes write module 166 to handle the command. In turn, write module 166 prompts data identifier 162 to determine whether (e.g. there is a high probability that) an identical copy of the data is already stored in memory 104 and notify controller 108 accordingly (e.g. by negating its BUSY signal or setting its READY bit). Consequently, controller 108 invokes copy module 106 to associate the host-specified destination logical address “LA8” with the same physical address “PA35”. The resulting associations between physical address “PA35” and the two logical addresses “LA7” and “LA8” is shown at 232. This way, the data stored in the physical memory address “PA35” is accessible by using either one of the source logical addresses “LA7” and “LA8”. Therefore, from the host device's standpoint, the data is stored in the intended host-specified logical address (i.e., “LA8”). However, from the memory's standpoint, the data is stored only in one physical place; namely in memory address “PA35”. That is, no actual data writing has occurred.

### Writing Data that is Referenced by Multiple Logical Addresses

As explained above, the multiple logical addresses that reference the same (i.e., common) physical address can be thought of as storing the same data, and the data that is actually stored in the common physical address may be thought of as being referenced by the multiple logical addresses. If not taken care of, referencing a physical address by multiple logical addresses may be problematic, as described below.

If particular data, which is stored in a particular physical address, is referenced by multiple logical addresses, it may occur that host device 150 issues a command to write data to a logical address, where this logical address is connected to other logical addresses (referencing a common physical address). This phenomenon may result from operations that follow virtual data writing or virtual data copying, as explained and demonstrated below.

As virtual data writing and virtual data copying result in two or more logical addresses referencing a common physical address, writing new data into the common physical address would result in overwriting the data previously written into the common physical address. As the overwritten data is referenced by other logical addresses, as explained above, the other logical addresses would no longer reference valid data.

Return again to the example where physical address “PA2” is referenced by logical addresses “LA2”, “LA10”, and “LA14”. Assume that host device 150 sends to storage device 100 a write command that includes new data and specifies the logical address “LA14” (for example) as the destination logical address of the new data. Write module 166, by interoperating with data identifier 162, employs the procedure described above to check whether the new data is already stored in memory 104. If the new data is not yet stored in memory 104, controller 108 invokes write module 166 to allocate a free physical address and write the new data into this free physical address. To that end, write module 166 uses the listing of the free physical addresses that is kept in free locations table 174. The solution is demonstrated in FIG. 5, which is described below.

FIG. 5 is another example LTP mapping table 172. The example shown in FIG. 5 demonstrates a method for protecting data in a physical address from being unintentionally overwritten during a data writing operation. The protected data in this example is referenced by several logical addresses.

Return again to the example above, where physical address “PA2” is referenced by logical addresses “LA2”, “LA10”, and “LA14” (as shown in FIG. 4). Assume again that host device 150 sends to storage device 100 the command mentioned to write the new data into the logical address “LA14”. As shown in FIG. 4, physical address “PA2” is referenced by logical addresses “LA14” and, in addition, by logical addresses “LA2” and “LA10”. Therefore, write module 166 refrains from physically writing the new data into physical address “PA2”. Instead, write module 166 searches in free locations table 174 for a free physical address into which the new data can be written. If, according to free locations table 174, there are two or more free physical addresses, any one of the free physical addresses may be selected for holding the new data. Returning again to FIG. 5, physical address “PA50” is assumed to be free and selected for holding the new data. Accordingly, controller 108 invokes write module 166 to write the new data into physical address “PA50” and to further associate the host-specified destination logical address “LA14” with physical address “PA50”. The association between the logical address “LA14” and physical address “PA50” (as a replacement address of physical address “PA2”) is shown at 310. If a free physical address is used to hold the new data, the indication in free locations table 174 indicating that the physical address is free is updated accordingly.

Associating logical address “LA14” with physical address “PA50” breaks the association previously created between logical address “LA14” and physical address “PA2”. Still, the new data is accessible by host device 150 from logical address “LA14”.

FIG. 6 shows an example source LA table 176 according to an example. FIG. 6 will be described in association with FIG. 1. Source LA table 176 includes a “data pattern identifier” field and a “source logical address” field. Source LA table 176 includes an entry for each data, or pattern of data that is stored in memory 104. By way of example, source LA table 176 includes four entries, i.e. entries 410, 412, 414 and 416, which respectively correspond to four distinct patterns of data. Each entry includes a data pattern identifier that characterizes a pattern of the pertinent data, and a logical address of the data. For example, entry 410 includes the data pattern identifier “5A32B9” that characterizes a pattern of data that is stored in logical address “LA3”; entry 412 includes the data pattern identifier “5832B9” that characterizes a pattern of data that is stored in logical address “LA1”, entry 414 includes the data pattern identifier “5D38B9” that characterizes a pattern of data that is stored in logical address “LA15”; entry 416 includes the data pattern identifier “5132B9” that characterizes a pattern of data that is stored in logical address “LA22”; and so on.

When controller 108 receives a command from host device 150 to write data into memory 104, controller 108 invokes write module 166. This, as a result, prompts pattern ID generator 164 to generate a data pattern identifier that characterizes the incoming data (i.e. the data to be written). Data pattern 162 then accesses source LA table 176 to check whether source LA table 176 has a matching data pattern identifier. Assume that data identifier 162 receives a command from host device 150 to write data “Data_1” into destination logical address “LA62”. Pattern ID generator 164 generates a data pattern identifier (e.g., “5132B9”) that characterizes the data “Data_1” and, then, checks whether source LA table 176 contains a matching data pattern identifier. As shown at 416, source LA table 176 contains a matching data pattern identifier (i.e., “5132B9”). As explained above, finding a data pattern identifier in source LA table 176 that matches the generated data pattern identifier implies that there is a high probability that an identical data is already stored in memory 104. In this example, finding a matching data pattern identifier means that the data stored in the logical address “LA22” (which is associated with the identifier “5132B9”) is expected to identical, or in high probability identical to the data “Data_1”. As a result, controller 108 verifies that the data is really identical (optional) and interprets the write command as a virtual write command and invokes copy module 106 to perform a virtual copy process and to associate source logical address “LA22” with the host-specified destination logical address “LA62”. More specifically, controller 108 accesses source LA table 176, retrieves the source logical address “LA22” from source LA table 176, and then transfers the two logical addresses to copy module 106, for performing the virtual copy operation described above.

### Implementing Pattern ID Generator 164 to Use a Hashing Mechanism

FIG. 7A shows a data identifier block diagram according to an example. FIG. 7A will be described in association with FIG. 1. In the example of FIG. 7A, pattern ID generator 164 is designed to generate a data pattern identifier for incoming data that are received from host device 150 by using a hash mechanism, such as hash mechanism 512. As explained above, the incoming data may be received from host device 150 as a single pattern of data, or it may be partitioned by storage device 100 to multiple patterns of data (e.g. data segments).

In general, hash mechanism 512 is operative to perform hash operations. A “hash operation” is a procedure provided to generate a value (i.e. hash value, or a pattern identifier) fixed in size that characterizes or represents a large, possibly variable-sized amount of data. The value generated by a hash operation typically serves as an index to a database, such as database 178.

Briefly, hash operations are used to speed up table lookup or data comparison tasks for finding items in a database, detecting duplicated or similar records in a large file, etc. Hash functions are also used to check the integrity of data. Hash operations are typically related to various decoding methods that use, for example, checksums, check digits, fingerprints, and cryptographic hash functions, among others.

Hash mechanism 512 may perform hash operations by using various hash algorithms, such as message digest (“MD”), secure hash algorithm (“SHA”), or the like, that typically take arbitrary-sized data and output a fixed-length hash value. A hash value, which is bit-wise shorter than the pertinent data, can be thought of as a signature, representation, or characterization of the data. For example, a data received from host device 150 may have 512 bytes, and hashing mechanism 512 may generate an 8-byte pattern identifier (i.e. hash value) as a signature, representation, or characterization of the 512-byte data. Hash algorithms are described in Applied Cryptography, Bruce Schneier, John Wiley & Sons, Inc. (ISBN 0471128457), incorporated by reference in its entirety for all purposes.

In another implementation, hash mechanism 512 may perform hash operations by using a cyclic redundancy check (“CRC”) scheme. The CRC is a commonly used technique implemented to obtain data reliability. The CRC scheme can be used to calculate a CRC character, or signature, for incoming data, and the CRC character can serve as the hash value, or data pattern identifier, that characterizes the incoming data.

Returning to FIG. 7A, hash mechanism 512 performs hash operations to detect whether data that is received from host device 150 is already stored in memory 104. When host device 150 sends a write command to storage device 100, the write command along with the write particulars (i.e. destination logical address and received data) are forwarded to data identifier 162, as shown at 514. Hash mechanism 512 receives the data (designated as “Data_1”) and performs hash operations to generate a hash value, or a data pattern identifier (DPI) that characterizes the received data (i.e. “Data_1”), by using any one of the techniques described above, among others. Data identifier 162 uses the generated hash value as a data pattern identifier (DPI) when searching for a matching DPI in database 178.

Note that with an incoming pattern of data being divided into segments of a predetermined size, hash mechanism 512 may perform a plurality of hash operations, where each hash operation is performed to generate a hash value, or a data pattern identifier (DPI) that characterizes a corresponding data segment.

### Implementing Hashing Mechanism by Using an Error Correction Code (ECC) Scheme

FIG. 7B shows a data identifier block diagram according to another example. FIG. 7B will be described in association with FIG. 1. In FIG. 7B, pattern ID generator 164 is designed to perform hashing operations by utilizing, or incorporating an Error Correction Code (ECC) mechanism 612. Again, pattern ID generator 164 is provided for the purpose of generating a data pattern identifier for incoming data that is received from host device 150.

In a typical data storage system design used today, ECC units or mechanisms are implemented to employ error detection and correction code algorithms, such as for checking for, and possibly correcting of, memory errors in received or stored data. These algorithms employ parity information (i.e. some extra data) in form of parity bits that are added to data bits of received data, which enables detection of any errors in the transmitted data. The way in which the parity bits are generated and further employed in an ECC scheme is well known in the art and may vary according to implementation. In general, the parity bits are generated from data bits of received data and then added to the received data. A parity bit is a bit that is added to ensure that the number of set bits (i.e., bits with the value 1) in a group of bits is even or odd. When the parity bits are later retrieved from the received data, the parity bits are recalculated by the ECC scheme utilizing the received data. If the recalculated parity bits not match the original redundant data bits (which were added to the originally received data), data corruption is detected, and possibly corrected.

In the context of this disclosure, the parity bits employed by ECC 612 are referred to as a data pattern identifier (DPI), for characterizing incoming data received from host device 150. Data identifier 162 uses the parity bits as a data pattern identifier (DPI) when searching for a matching DPI in database 178. More specifically, data identifier 162 uses the generated data pattern identifier (or parity bits) to compare it with other data pattern identifiers previously stored in data base 178 and determine whether the data that is received from host device 150 is already stored in memory 104. Per FIG. 7B, when host device 150 sends a write command to storage device 100, the write command along with the write particulars (i.e. destination logical address and received data) are forwarded to data identifier 162, as shown at 614. ECC unit 612 receives the data (designated as “Data_2”) and employs error correction code algorithm that add parity bits to the received data. Data identifier 162 then uses these parity bits as a data pattern identifier (DPI), which characterizes the received data, when searching for a matching DPI in database 178.

Using an ECC scheme for performing the hashing operations and obtaining data pattern identifiers as such is cost-effective, particularly in flash-based storage devices that have an ECC scheme (or EDC scheme, for example) as an integral part of their design.

It should be noted that many alternatives can be used with each of these embodiments. For example, the data identifier 162 may be implemented in hardware, software, firmware, or in any combination thereof, and may be integrated within and executed by the controller 108 for analyzing an incoming pattern of data and determining whether or not a previous copy has already been stored in the memory. Again, with an incoming pattern of data being divided into segments of a predetermined size, a plurality of hash operations may be performed for characterizing the received data, where each hash operation is performed to generate a hash value, or a data pattern identifier (DPI) that characterizes a corresponding data segment.

The storage device 100 may have a configuration that complies with any memory type (e.g. flash memory), Trusted Flash device, Secure Digital (“SD”), mini SD, micro SD, Hard Drive (“HD”), Memory Stick (“MS”), USB device, Disk-on-Key (“DoK”), and the like, and with embedded memory and memory card format, such as a secured digital (SD) memory card format used for storing digital media such as audio, video, or picture files. The storage device 100 may also have a configuration that complies with a multi media card (MMC) memory card format, a compact flash (CF) memory card format, a flash PC (e.g., ATA Flash) memory card format, a smart-media memory card format, a USB flash drive, or with any other industry standard specifications. One supplier of these memory cards and others is SanDisk Corporation, assignee of this application.

The storage device may also have a configuration complying with a high capacity subscriber identity module (SIM) (HCS) memory card format. The high capacity SIM (HCS) memory card format is a secure, cost-effective and high-capacity storage solution for the increased requirements of multimedia handsets, typically configured to use a host's network capabilities and/or other resources, to thereby enable network communication.

The storage device is a nonvolatile memory that retains its memory or stored state even after power is removed. Note that the device configuration does not depend on the type of removable memory, and may be implemented with any type of memory, whether it is a flash memory or another type of memory.

Host devices, with which such storage devices are used, may include not only personal computers (PCs) but also cellular telephones, notebook computers, hand held computing devices, cameras, audio reproducing devices, and other electronic devices requiring removable data storage. Flash EEPROM systems are also utilized as bulk mass storage embedded in host systems. The storage device may be connected to or plugged into a compatible socket of a PDA (Personal Digital Assistant), mobile handset, and other various electronic devices. A PDA is typically known as a user-held computer system implemented with various personal information management applications, such as an address book, a daily organizer, and electronic notepads, to name a few.

It is intended that the foregoing detailed description be understood as an illustration of selected forms that the embodiments can take and does not intend to limit the claims that follow. Also, some of the following claims may state that a component is operative to perform a certain function or configured for a certain task. It should be noted that these are not restrictive limitations. It should also be noted that the acts recited in the claims can be performed in any order—not necessarily in the order in which they are recited. Additionally, any aspect of any of the preferred embodiments described herein can be used alone or in combination with one another. In sum, although the present invention has been described in considerable detail with reference to certain embodiments thereof, other versions are possible. Therefore, the spirit and scope of the appended claims should not be limited to the description of the embodiments contained herein.

What is claimed is:

1. A method of copying data on a storage device, comprising:
in a storage device including a memory and a controller for managing the memory, wherein the controller includes a first executable module, and wherein data are stored in the memory in physical memory addresses that are associated with logical memory addresses, performing by the first executable module:
receiving a command to copy data from a source logical memory address to a destination logical memory address, the source logical memory address data being already associated with a first physical memory address storing the data; and
in response to receiving the command, associating the first physical memory address with the destination logical memory address such that the data stored in the first physical memory address is accessible by using the source logical memory address or the destination logical memory address.

2. The method of claim 1, wherein subsequent to associating the first physical memory address with the destination logical memory address, the first physical memory address is associated at least with the source logical memory address and the destination logical memory address.

3. The method of claim 1, wherein receiving the command comprises receiving a copy command from a host device in communication with the storage device.

4. The method of claim 1, wherein the controller further includes a second executable module, the controller executing the second executable module to identify whether a previous copy of the data is stored in the storage device.

5. The method of claim 4, wherein receiving the command comprises receiving a write command from a host device in communication with the storage device, and executing a virtual copy procedure within the storage device when the second executable module identifies the previous copy of the data in the storage device.

6. The method of claim 5, wherein the controller further includes a verification module, the verification module verifying that the previous copy of the data in the storage device is identical to the data received by the command prior to executing the virtual copy procedure.

7. The method of claim 4, wherein identifying the previous copy of the data in the storage device involves performing hash operations.

8. The method of claim 7, wherein the second executable module utilizes an error correction code (ECC) for performing the hash operations.

9. The method of claim 1, wherein when the command comprises a write command for new data and identifies a destination logical address currently associated with the first physical address, and the first physical address is already associated with at least two logical addresses, the method further comprises:
allocating a free physical address for the new data;
writing the new data to the allocated free physical address; and
associating the destination logical address with the allocated free physical address, wherein the destination logical address and the first physical address are no longer associated.

10. A storage device, comprising:
a memory, where data are stored in physical memory addresses that are associated with logical memory addresses; and
a controller for managing the memory, the controller including a first executable module, the first executable module configured to:
receive a command to copy data from a source logical memory address to a destination logical memory address, the source logical memory address data being already associated with a first physical memory address storing the data; and
in response to the received command, associate the first physical memory address with the destination logical memory address such that the data stored in the first physical memory address is accessible by using either one of the source logical memory address and the destination logical memory address.

11. The storage device of claim 10, wherein subsequent to associating the first physical memory address with the destination logical memory address, the first physical memory address is associated at least with the source logical memory address and the destination logical memory address.

12. The storage device of claim 11, wherein the command to copy the data is a copy command received from a host device in communication with the storage device.

13. The storage device of claim 11, wherein the controller further includes a second executable module, the second executable module configured to identify a previous copy of the data in the storage device.

14. The storage device of claim 13, wherein the controller is configured to internally generate the command to copy the data, in response to a write command received from a host device in communication with the storage device, upon identification by the second executable module of the previous copy of the data in the storage device.

15. The storage device of claim 13, wherein the controller further includes a verification module operable to verify that the previous copy of the data in the storage device is identical to the data received with the write command.

16. The storage device of claim 13, wherein the second executable module is configured to identify the previous copy of the data in the storage device by performing hash operations.

17. The storage device of claim 16, wherein the second executable module is configured to utilize with an error correction code (ECC) for performing the hash operations.

18. A method of copying data on a storage device, comprising:
in a storage device including a memory and a controller for managing the memory, wherein data are stored in the memory in physical memory addresses that are associated with logical memory addresses, performing by the controller:
receiving a command from a host;
determining if data associated with the command is already stored in the memory; and
in response to determining that the data associated with the command is already stored at a physical address in the memory associated with an existing logical address:
associating a destination logical address contained in the received command with the physical address of the data already stored in the memory, wherein the data is accessible by the host via either the destination logical address or the existing logical address.

19. The method of claim 18, wherein the command comprises a write command and further comprising, in response to determining that the data associated with the write command is not already stored in the memory, writing the data associated with the write command to a physical address in the memory.

20. The method of claim 18, wherein determining if the data associated with the command is already stored comprises the controller generating a data pattern identifier for the data associated with the command and comparing the generated data pattern identifier with previously generated data pattern identifiers for data already stored in the memory.

21. The method of claim 20, wherein generating a data pattern identifier comprises applying a hashing algorithm to the data associated with the command.
